(19) United States
(12) Patent Application Publication
(10) Pub. No.: US 2013/0056714 A1
(43) Pub. Date: Mar. 7, 2013

(54) ORGANIC EL DISPLAY, METHOD OF PRODUCING ORGANIC EL DISPLAY, AND ELECTRONIC UNIT

(71) Applicants: Eiji Hasegawa, Kanagawa (JP); Atsuya Makita, Kanagawa (JP); Jiro Yamada, Kanagawa (JP); Seiichi Yokoyama, Kanagawa (JP); Hidetoshi Noda, Nagasaki (JP); Hiroshi Sagawa, Kanagawa (JP)

(72) Inventors: Eiji Hasegawa, Kanagawa (JP); Atsuya Makita, Kanagawa (JP); Jiro Yamada, Kanagawa (JP); Seiichi Yokoyama, Kanagawa (JP); Hidetoshi Noda, Nagasaki (JP); Hiroshi Sagawa, Kanagawa (JP)

(73) Assignee: SONY CORPORATION, Tokyo (JP)

(21) Appl. No.: 13/594,274

(22) Filed: Aug. 24, 2012

(30) Foreign Application Priority Data
Sep. 1, 2011 (JP) 2011-191035

(51) Int. Cl. H01L 27/32; H01L 51/56

(52) U.S. Cl. 257/40; 438/23; 257/E27.119; 257/E51.018

(57) ABSTRACT

An organic EL display includes: a plurality of first electrodes provided in a display region on a drive substrate, the plurality of first electrodes each including a laminated film having two or more layers; an organic layer provided on the plurality of first electrodes and including a light emitting layer; an electrode pad provided in a peripheral region around the display region; and a second electrode provided on the organic layer as well as the electrode pad, wherein the laminated film includes a first conductive film functioning as a reflective film, and a second conductive film provided below the first conductive film, and having a reflectance lower than that of the first conductive film, and the electrode pad corresponds to a part of the laminated film, and includes a conductive film made of a material same as that of the second conductive film.

### BACKGROUND

The disclosure relates to an organic electroluminescence (EL) display that displays an image by using an organic EL phenomenon of an organic material.

An organic EL display of a top emission type has a device structure in which an organic EL layer is interposed between a lower electrode (e.g., an anode electrode) and an upper electrode (e.g., a cathode electrode). The lower electrode functions as a reflecting electrode. In this device structure, light is extracted from the upper electrode side (see Japanese Unexamined Patent Application Publication No. 2004-252406, for example). Such an organic EL display is allowed to be made as a small and high-definition display having a pixel pitch of about a few micrometers, by forming the device structure on a silicon wafer. However, in a case where a light emitting layer of each of pixels for red (R), green (G), and blue (B) is formed (to have the corresponding color) by evaporation method using an evaporation mask, alignment precision of the mask tends to become insufficient, when the pixel pitch is made fine as mentioned above. For this reason, there is adopted a so-called RGB-White method in which, for example, light emitting layers of the respective three colors are laminated over all the pixels, and white emitted light is extracted.

### SUMMARY

However, in the RGB-White method, the light emitting layers are deposited over the entire light emission region (a display region). Thus, it is difficult to form, in the light emission region, a pad or the like used to take out the upper electrode (the cathode electrode) (i.e. used to establish wiring connection to the cathode electrode). Therefore, it is necessary to provide the pad for cathode connection (hereinafter referred to as “electrode pad”), outside the light emission region.

This electrode pad may be formed at the same level (in the same process) as a wiring layer such as a thin-film transistor (TFT) disposed below a light-emission device. In this case however, multiple layers are present between the electrode pad and the cathode electrode. Therefore, there is a great level difference between the electrode pad and the cathode electrode, causing the cathode electrode to be locally thin or have breaks easily. It is to be noted that an influence of this level difference is mitigated by increasing the thickness of the cathode electrode. However, when the thickness is increased, light extraction efficiency decreases because of light absorption in the cathode electrode. This leads to such a disadvantage that visibility in a displayed image drops.

It is desirable to provide an organic EL display, a method of producing the organic EL display, and an electronic unit, which are capable of realizing a size reduction and high definition, without reducing visibility of a displayed image.

According to an embodiment of the disclosure, there is provided an organic EL display including: a plurality of first electrodes provided in a display region on a drive substrate, the plurality of first electrodes each including a laminated film having two or more layers; an organic layer provided on the plurality of first electrodes, the organic layer being provided over the entire display region and including a light emitting layer; an electrode pad provided in a peripheral region around the display region on the drive substrate; and a second electrode provided on the organic layer as well as the electrode pad, wherein the laminated film includes a first conductive film functioning as a reflective film, and a second conductive film provided below the first conductive film, and having a reflectance lower than that of the first conductive film, and the electrode pad corresponds to a part of the laminated film, and includes a conductive film made of a material same as that of the second conductive film.

In the organic EL display according to the embodiment of the disclosure, each of the first electrodes provided in the display region on the drive substrate includes the laminated film having the second conductive film. The second conductive film is provided below the first conductive film (the reflective film) and has the reflectance lower that that of the first conductive film. The electrode pad connected to the second electrode in the peripheral region includes at least the conductive film made of the same material as that of the second conductive film of the laminated film. In each of the first electrodes, a function of the first conductive film as the reflective film of the laminated film is exhibited, while in the electrode pad, external light reflection is suppressed by the conductive film made of the same material as that of the second conductive film having the low reflectance.

According to an embodiment of the disclosure, there is provided a method of producing an organic EL display, the method including: forming a plurality of first electrodes in a display region on a drive substrate, the plurality of first electrodes each including a laminated film having two or more layers; forming an organic layer provided on the plurality of first electrodes, the organic layer being provided over the entire display region and including a light emitting layer; forming an electrode pad in a peripheral region around the display region on the drive substrate; and forming a second electrode on the organic layer as well as the electrode pad, wherein in forming the plurality of first electrodes, a first conductive film and a second conductive film provided below the first conductive film are formed as the laminated film, the first conductive film functioning as a reflective film, and the second conductive film having a reflectance lower than that of the first conductive film, and in forming the electrode pad, a conductive film corresponding to a part of the laminated film is formed as the electrode pad, the conductive film being made of a material same as that of the second conductive film.

In the method of producing the organic EL display according to the embodiment of the disclosure, the laminated film including the second conductive film is formed as the first electrode, in the display region on the drive substrate. The second conductive film is provided below the first conductive film (the reflective film) and has the reflectance lower than that of the first conductive film. In the peripheral region, the electrode pad including at least the second conductive film of the laminated film is formed. While the first electrode and the electrode pad are formed in the same process, the first electrode is allowed to exhibit a function of reflective film, and the electrode pad is allowed to suppress external light reflection.

According to an embodiment of the disclosure, there is provided an electronic unit including an organic EL display, the organic EL display including: a plurality of first electrodes provided in a display region on a drive substrate, the plurality of first electrodes each including a laminated film having two or more layers; an organic layer provided on the plurality of first electrodes, the organic layer being provided over the entire display region and including a light emitting layer; an electrode pad provided in a peripheral region around the display region on the drive substrate; and a second electrode provided on the organic layer as well as the electrode pad, wherein the laminated film includes a first conductive film functioning as a reflective film, and a second conductive film provided below the first conductive film, and having a reflectance lower than that of the first conductive film, and the electrode pad corresponds to a part of the laminated film, and includes a conductive film made of a material same as that of the second conductive film.

According to the organic EL display, the method of producing the organic EL display, and the electronic unit in the embodiments of the disclosure, each of the first electrodes provided in the display region on the drive substrate includes the laminated film that has the second conductive film. The second conductive film is provided below the first conductive film (the reflective film), and has the reflectance lower that that of the first conductive film. The electrode pad connected to the second electrode in the peripheral region includes at least the second conductive film of the laminated film. This allows a reflection function to be exhibited in the first electrode, while suppressing external light reflection in the electrode pad. Therefore, a size reduction and high definition are allowed to be realized, without a drop in visibility of a displayed image.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a diagram illustrating a cross-sectional configuration of an organic EL display according to a first embodiment of the disclosure.

FIGS. 2A and 2B are cross-sectional diagrams used to explain a method of producing the organic EL display illustrated in FIG. 1.

FIGS. 3A and 3B are cross-sectional diagrams illustrating a process following FIGS. 2A and 2B.

FIG. 4 is a cross-sectional diagram illustrating a process following FIGS. 3A and 3B.

FIG. 5 is a cross-sectional diagram illustrating a process following FIG. 4.

FIG. 6 is a cross-sectional diagram illustrating a process following FIG. 5.

FIG. 7 is a cross-sectional diagram illustrating a process following FIG. 6.

FIG. 8 is a cross-sectional diagram illustrating a process following FIG. 7.

FIG. 9 is a cross-sectional diagram illustrating a process following FIG. 8.

FIG. 10 is a cross-sectional diagram illustrating a process following FIG. 9.

FIG. 11 is a diagram illustrating a cross-sectional configuration of an organic EL display according to a second embodiment of the disclosure.

FIG. 12 is a cross-sectional diagram used to explain a method of producing the organic EL display illustrated in FIG. 11.

FIGS. 13A to 13C are enlarged cross-sectional diagrams used to explain a process of forming a contact layer.

FIG. 14 is an enlarged cross-sectional diagram of the contact layer.

FIG. 15 is a cross-sectional diagram illustrating a process following FIG. 12.

FIG. 16 is a cross-sectional diagram illustrating a process following FIG. 15.

FIG. 17 is a cross-sectional diagram illustrating a process following FIG. 16.

FIG. 18 is a cross-sectional diagram illustrating a process following FIG. 17.

FIG. 19 is a cross-sectional diagram illustrating a process following FIG. 18.

FIG. 20 is a cross-sectional diagram illustrating a process following FIG. 19.

FIG. 21 is a cross-sectional diagram illustrating a process following FIG. 20.

FIG. 22 is a cross-sectional diagram illustrating a process following FIG. 21.

FIG. 23 is a diagram illustrating an overall configuration including peripheral circuits of the display according to each of the embodiments.

FIG. 24 is a diagram illustrating a circuit configuration of a pixel depicted in FIG. 23.

FIG. 25 is a plan view illustrating a schematic configuration of a module including the display depicted in FIG. 23.

FIG. 26 is a perspective diagram illustrating an appearance of an application example 1 of the display according to the embodiments or the like.

FIGS. 27A and 27B are perspective diagrams of an application example 2, namely, FIG. 27A illustrates an appearance when viewed from front, and FIG. 27B illustrates an appearance when viewed from back.

FIG. 28 is a perspective diagram illustrating an appearance of an application example 3.

FIG. 29 is a perspective diagram illustrating an appearance of an application example 4.

FIGS. 30A to 30G are diagrams of an application example 5, namely, a front view in an open state, a side view in the open state, a front view in a closed state, a left-side view, a right-side view, a top view, and a bottom view, respectively.

### DETAILED DESCRIPTION

Embodiments of the disclosure will be described below in detail with reference to the drawings. It is to be noted that the description will be provided in the following order.
1. First embodiment (an example in which a layer used as an electrode pad is equivalent to a laminated layer which forms a first electrode and from which a first conductive film (a high reflective film) is almost entirely removed)
2. Second embodiment (an example in which a layer used as an electrode pad is equivalent to a laminated layer which forms a first electrode and from which a first conductive film (a high reflective film) is partially removed)
3. Application examples (examples of application to electronic units)

### First Embodiment

### [Configuration]

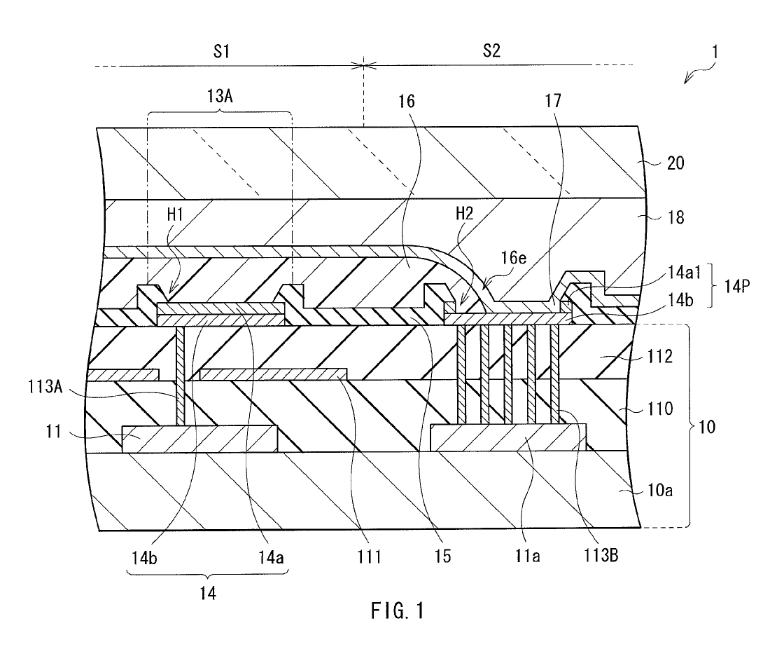

FIG. 1 illustrates a cross-sectional configuration of an organic EL display (an organic EL display 1) according to a first embodiment of the disclosure. The organic EL display 1 is, for example, of a so-called top emission type. In the organic EL display 1, for instance, a plurality of organic EL devices (EL device sections 13A) are disposed in a matrix, in a display region S1 on a drive substrate 10. It is to be noted that FIG. 1 illustrates one of the EL device sections 13A and an electrode pad 14P (in the neighborhood of a border between the display region Si and a peripheral region S2) to be described later. Each of the EL device sections 13A forms, for example, any of three subpixels of red (R), green (G), and blue (B), and these three subpixels function as one pixel.

### (Drive Substrate 10)

In the drive substrate 10, a drive circuit (a pixel circuit 40 to be described later and the like) including a TFT 11 is disposed on a substrate 10a made of amorphous silicon, for example. However, the substrate 10a is not limited to amorphous silicon, and may be made of polysilicon, quartz, glass, metal foil, silicon, plastic, or the like.

The TFT 11 corresponds to, for example, a sampling transistor 3A or a write transistor 3B in the pixel circuit 40 which will be described later. The TFT 11 may be, for example, in an inverted staggered structure (a so-called bottom gate type), or a staggered structure (a top gate type). A first insulating film 110 covering the TFT 11 is provided on the substrate 10a. On the first insulating film 110, a wiring layer 111 used to form a capacitive device and the like is provided. A second insulating film 112 is formed over an entire substrate surface, to cover the wiring layer 111. It is desirable that the first insulating film 110 be made of, for example, silicon oxynitride (SiON) or silicon monoxide (SiO), and the second insulating film 112 be made of, for example, silicon dioxide (SiO₂). In the first insulating film 110 and the second insulating film 112, a contact layer 113A and a contact layer 113B are embedded in a region corresponding to the EL device section 13A and in a region corresponding to the electrode pad 14P, respectively. It is to be noted that in FIG. 1, one of the contact layers 113A and some (here, five) of the contact layers 113B are illustrated. However, the number, diameter, and the like of the contact layers 113A and 113B are not limited to those illustrated.

The contact layers 113A and 113B are each formed by, for example, filling a contact hole passing through the first insulating film 110 and the second insulating film 112, with a conductive material. Tungsten (W), for instance, may be used as the conductive material. The contact layer 113A electrically connects a lower electrode (a first electrode 14) of the EL device section 13A to an electrode (e.g., a source or a drain) of the TFT 11. The contact layer 113B electrically connects a conductive film (a low-reflection conductive film 14b) of the electrode pad 14P to a wiring layer 11a. The wiring layer 11a is formed at the same level as the TFT 11, on the substrate 10a.

### (EL Device Section 13A)

The EL device section 13A causes light emission using, for example, a top emission method. The EL device section 13A includes, for instance, the first electrode 14, an organic layer 16, and a second electrode 17 provided on the second insulating film 112 of the drive substrate 10. Further, on the first electrode 14, an inter-pixel insulating film 15 is formed over the entire substrate surface. The inter-pixel insulating film 15 has an opening H1 facing the first electrode 14 and an opening H2 facing the electrode pad 14P. A region facing the opening H1 of the inter-pixel insulating film 15 is a light emission region in each of the EL device sections 13A.

The inter-pixel insulating film 15 has a function of electrically separating the EL device sections 13A from one another (i.e., partitioning a pixel opening), and is configured using, for example, an inorganic insulating film made of silicon oxide (SiO₂) or the like. The inter-pixel insulating film 15 has a thickness of, for example, about 10 nm to about 200 nm.

The first electrode 14 is provided for every pixel, and functions as an anode as well as a reflecting electrode, for example. In the present embodiment, the first electrode 14 includes a high-reflection conductive film 14a serving as a reflective film, and further includes the low-reflection conductive film 14b provided below the high-reflection conductive film 14a. In other words, the first electrode 14 is a laminated film having the low-reflection conductive film 14b and the high-reflection conductive film 14a provided sequentially from the drive substrate 10 side.

For instance, aluminum (Al) or an alloy containing aluminum (e.g., an alloy of aluminum and neodymium (Nd)) is suitable for the high-reflection conductive film 14a. Alternatively, for example, a simple substance or an alloy of silver (Ag) (e.g., an alloy of magnesium (Mg) and silver) may be used. The high-reflection conductive film 14a has, for example, a thickness of about 20 nm to about 600 nm.

It is desirable that the low-reflection conductive film 14b be made of a conductive-film material having a reflectance lower than that of the high-reflection conductive film 14a. For example, being made of titanium (Ti), titanium nitride (TiN), or an alloy containing titanium is desirable. The first electrode 14 is electrically connected to an electrode of the TFT 11 through the contact layer 113A as described above. In a case where tungsten is used for the contact layer 113A, a reaction occurs when tungsten is in direct contact with aluminum (the high-reflection conductive film 14a). Therefore, the low-reflection conductive film 14b made of titanium or titanium nitride is provided therebetween, thereby functioning as a barrier metal, which allows the reaction to be suppressed. This low-reflection conductive film 14b has, for example, a thickness of about 5 nm to about 100 nm.

The organic layer 16 includes, for example, an organic EL layer that emits white light (hereinafter referred to as “white light emitting layer”). When an electric field is applied through the first electrode 14 and the second electrode 17, electron-hole recombination occurs and thereby the white light is produced.

Specifically, the white light emitting layer has, for example, a structure (a tandem structure) in which a red light emitting layer emitting red light, a green light emitting layer emitting green light, and a blue light emitting layer emitting blue light are laminated. The red light emitting layer includes, for example, one or more kinds of a red luminescent material, a hole-transporting material, and an electron-transporting material. The red light emitting layer is configured using, for example, 4,4-bis(2,2-diphenylvinyl)biphenyl (DPVBi), mixed with 2,6-bis[(4′-methoxy-diphenylamino)styryl]-1,5-dicyanonaphthalene (BSN). The green light emitting layer includes, for example, one or more kinds of a green luminescent material, a hole-transporting material, and an electron-transporting material, and is configured using, for example, ADN or DPVBi mixed with coumarin 6. The blue light emitting layer includes, for example, one or more kinds of a blue luminescent material, a hole-transporting material, and an electron-transporting material. The blue light emitting layer is configured using, for example, DPVBi mixed with 4,4′-bis[2-(4-(N,N-diphenylamino)phenyl)vinyl]biphenyl (DPAVBi).

The organic layer 16 may include, for example, a hole injection layer, a hole transport layer, an electron transport layer, and the like, in addition to the light emitting layer described above. Specifically, in a case where the first electrode 14 functions as an anode, there may be adopted a structure in which the hole injection layer, the hole transport layer, the white light emitting layer, and the electron transport layer are sequentially laminated from the first electrode 14 side. The organic layer 16 having such a layered structure may be formed as a layer common to all the EL device sections 13A on the drive substrate 10. Alternatively, one or more layers of the organic layer 16 may be provided for each of the EL device sections 13A, while other layers may be provided to be common to all the EL device sections 13A. In addition, an electron injection layer made of, for example, LiF may be further provided between the organic layer 16 and the second electrode 17.

It is to be noted that, the layer in which the red light emitting layer, the green light emitting layer, and the blue light emitting layer are laminated is described as an example of the white light emitting layer. However, the white light emitting layer is not limited to this example, and may be in any type of structure as long as it is capable of producing white light by mixing colors. For example, there may be employed a structure in which a blue light emitting layer and an orange light emitting layer are laminated, or a structure in which a blue light emitting layer and a yellow light emitting layer are laminated.

The second electrode 17 is, for instance, provided to be common to all the EL device sections 13A on the drive substrate 10, and functions as a cathode, for example. The second electrode 17 is configured using, for example, a compound of indium oxide (e.g., indium tin oxide (ITO), or indium oxide zinc (IZO)), or a co-deposited film of magnesium (Mg) and silver (i.e., a MgAg co-deposited film). The second electrode 17 is electrically connected to the electrode pad 14P in the opening H2 of the inter-pixel insulating film 15 to be described later.

### (Electrode Pad 14P)

In the present embodiment, the electrode pad 14P corresponding to a part of the laminated film in the first electrode 14 is provided in the peripheral region S2 (a frame region) around the display region S1 including the EL device section 13A described above. The electrode pad 14P is provided as a wiring-connection pad of the second electrode 17. Specifically, the electrode pad 14P has a structure that includes at least the low-reflection conductive film 14b in the laminated film of the first electrode 14. For example, in the electrode pad 14P, the low-reflection conductive film 14b is provided, and the high-reflection conductive film 14a is provided only at an edge on the low-reflection conductive film 14b. As will be described later in detail, the electrode pad 14P is formed by forming the laminated film including the high-reflection conductive film 14a and the low-reflection conductive film 14b in the same process as that of the first electrode 14, and then selectively removing a part corresponding to the high-reflection conductive film 14a. It is to be noted that in the electrode pad 14P, the high-reflection conductive film 14a may be entirely removed.

As described above, the electrode pad 14P is in contact with the second electrode 17, in the opening H2 of the inter-pixel insulating film 15. This ensures electrical connection with the second electrode 17. In the present embodiment, the organic layer 16 is formed to extend from the display region S1, to cover a part of the electrode pad 14P in the peripheral region S2. An end section 16e slopes gently towards the electrode pad 14P. The second electrode 17 is formed over the entire substrate surface, along a slope of the organic layer 16.

Provided on the second electrode 17 is a protective layer 18. The protective layer 18 has, for example, a thickness of about 2 μm to about 5 μm, and may be configured using either an insulating material or a conductive material. It is preferable to use an inorganic amorphous insulating material as the insulating material. Examples of the inorganic amorphous insulating material include amorphous silicon (a-Si), amorphous silicon carbide (a-SiC), amorphous silicon nitride (a-Si₁-xNx), and amorphous carbon (a-C). Such an inorganic amorphous insulating material does not form grains and thus has low permeability, thereby forming a satisfactory protective film. Onto the protective layer 18, a sealing substrate 20 is adhered with an adhesive layer not illustrated.

The sealing substrate 20 seals each of the EL device sections 13A in cooperation with the protective layer 18. The sealing substrate 20 is configured using, for example, a material such as glass transparent to color light of each of R, G, and B. The sealing substrate 20 may be provided with a color filter not illustrated. The color filter includes, for instance, red, green, and blue filters, and is made of resin mixed with, for example, a pigment or dye. Provision of such a color filter allows the light (here, white light) produced in each of the EL device sections 13A to be converted into R, G, or B color light and then extracted.

### [Production Method]

The organic EL display 1 described above may be produced as follows.

### (Process of Forming Drive Substrate)

First, the drive substrate 10 is prepared. Specifically, on the substrate 10a made of the material described above, a drive circuit including the TFT 11 is formed by undergoing a predetermined thin film process. Subsequently, the first insulating film 110 made of the material described above is formed over the entire surface of the substrate 10a by CVD (Chemical Vapor Deposition), for example. On the first insulating film 110 thus formed, pattern formation of the wiring layer 111 is performed. After that, the second insulating film 112 made of the material described above is formed over the entire surface of the substrate 10a by CVD, for example.

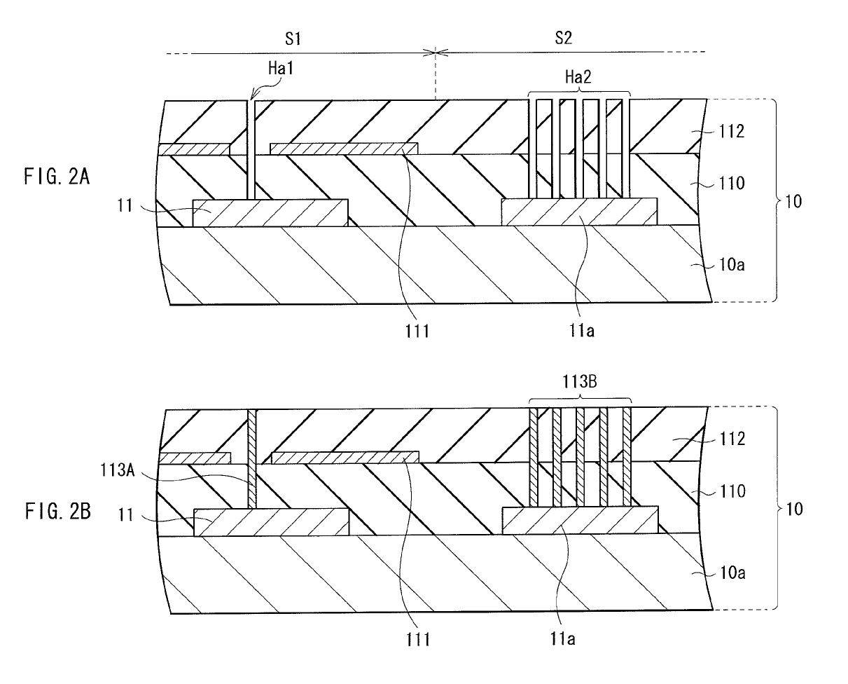

Next, a contact hole Hal and contact holes Ha2 for the contact layers 113A and 113B, respectively, are formed in the first insulating film 110 and the second insulating film 112 on the substrate 10a, as illustrated in FIG. 2A. Specifically, selective regions of the first insulating film 110 and the second insulating film 112 are removed by dry etching using photolithography, to form the contact holes Ha1 and Ha2 passing therethrough up to a surface of the TFT 11 or a surface of the wiring layer 11a.

The contact holes Ha1 and Ha2 are filled with a conductive material such as tungsten by sputtering, for example, as illustrated in FIG. 2B. In this way, the drive substrate 10 having the contact layers 113A and 113B is formed.

### (Process of Forming First Electrode and Electrode Pad)

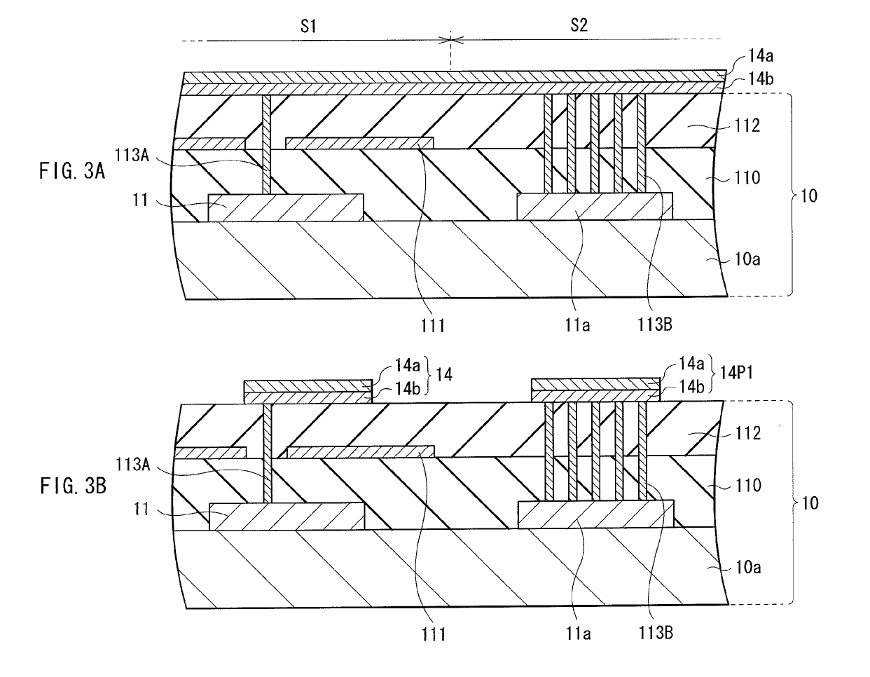

Next, the low-reflection conductive film 14b and the high-reflection conductive film 14a each made of the material described above are formed in this order by sputtering, for example, over the entire surface of the drive substrate 10 as illustrated in FIG. 3A. Subsequently, patterning is performed by dry etching using photolithography, for example, as illustrated in FIG. 3B. As a result, the first electrode 14 including the low-reflection conductive film 14b and the high-reflection conductive film 14a is formed in the display region 51, and a laminated film 14P1 having a similar configuration is formed in the peripheral region S2. The first electrode 14 is electrically connected to the TFT 11 through the contact layer 113A. In the peripheral region, the low-reflection conductive film 14b (a part corresponding to the electrode pad 14P) of the laminated film 14P1 is electrically connected to the wiring layer 11a through the contact layer 113B.

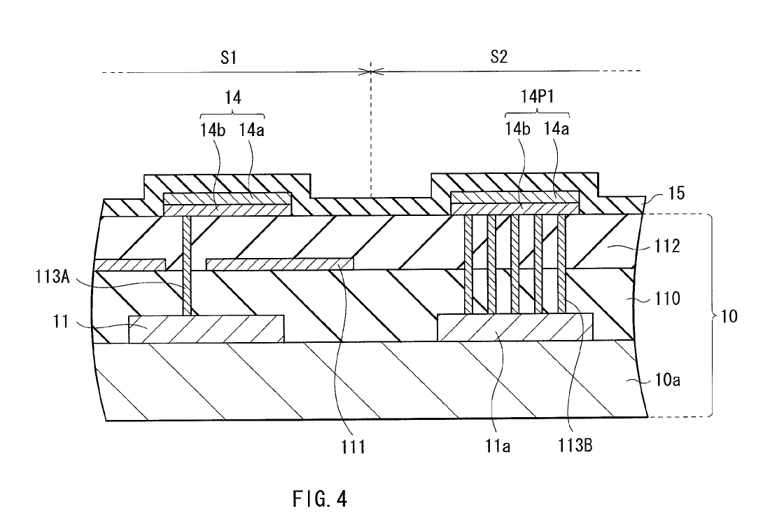

Subsequently, as illustrated in FIG. 4, the inter-pixel insulating film 15 made of the material described above is formed over the entire surface of the drive substrate 10, by plasma CVD (plasma-enhanced chemical vapor deposition), for example.

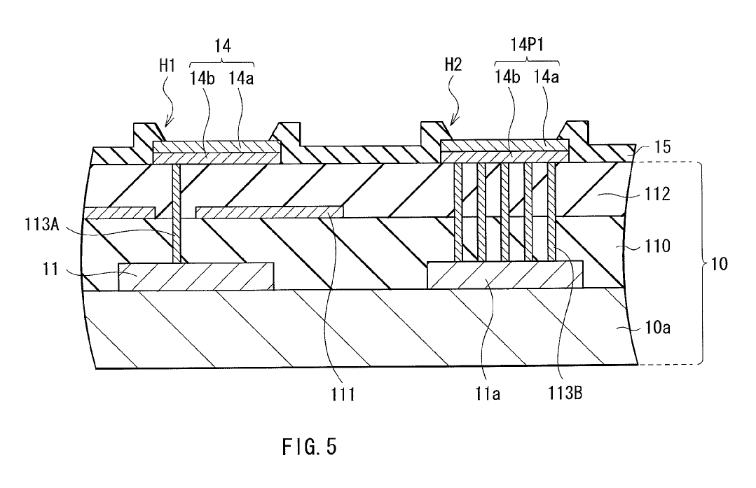

Afterwards, of the inter-pixel insulating film 15, a region facing the first electrode 14 and a region facing the laminated film 14P1 are selectively removed by dry etching using photolithography, for example. The openings H1 and H2 are thereby formed, as illustrated in FIG. 5.

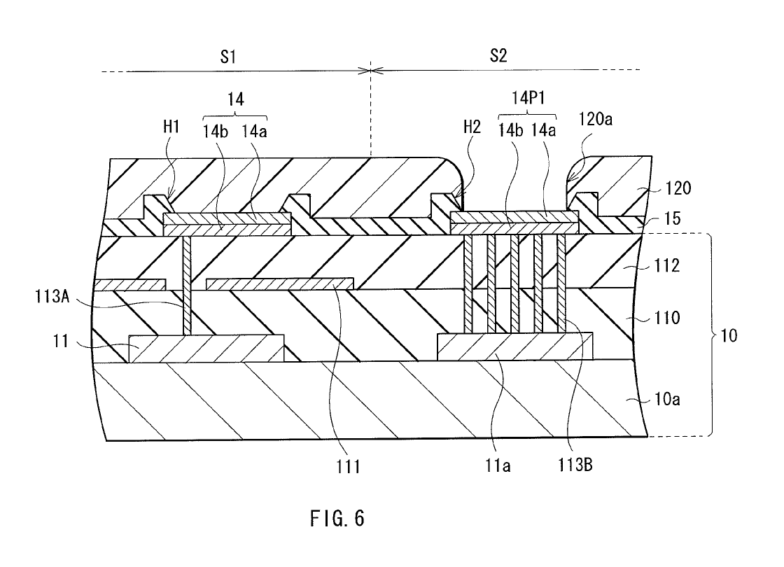

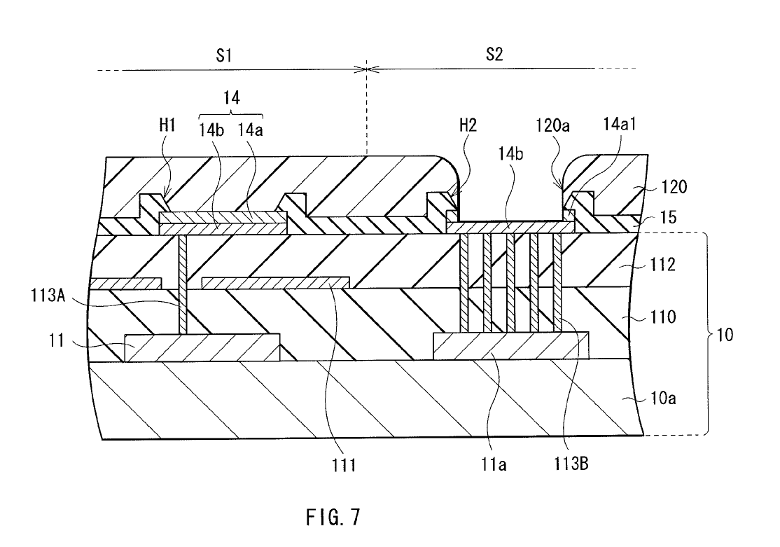

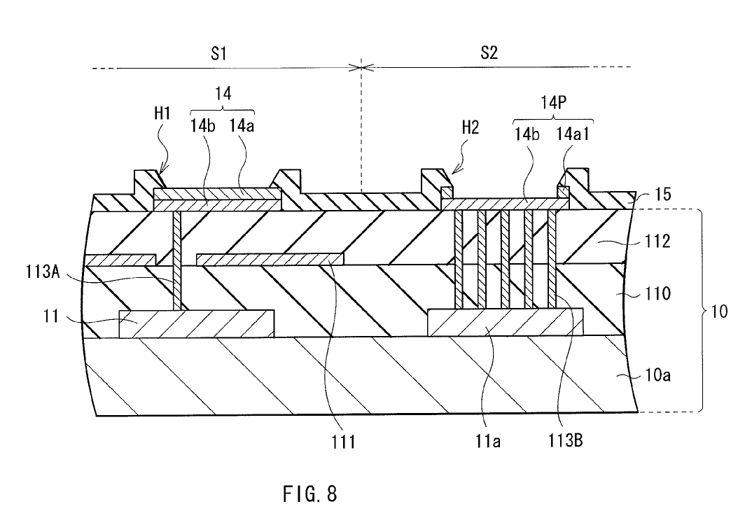

Next, the high-reflection conductive film 14a of the laminated film 14P1 formed in the peripheral region S2 is selectively removed. Specifically, first, a photoresist film 120 having an opening 120a facing the laminated film 14P1 (i.e. facing the opening H2) is formed, as illustrated in FIG. 6. Subsequently, as illustrated in FIG. 7, only the high-reflection conductive film 14a of the laminated film 14P1 is selectively removed by, for example, dry etching or wet etching. Specifically however, the inter-pixel insulating film 15 and the photoresist film 120 are formed to overlap an edge of the laminated film 14P1. Therefore, an end portion (14a1) of the high-reflection conductive film 14a remains on the low-reflection conductive film 14b, without being removed. Afterwards, as illustrated in FIG. 8, the electrode pad 14P including the low-reflection conductive film 14b (specifically, also including the end portion 14a1) is formed by removing the photoresist film 120.

### (Process of Forming Organic Layer)

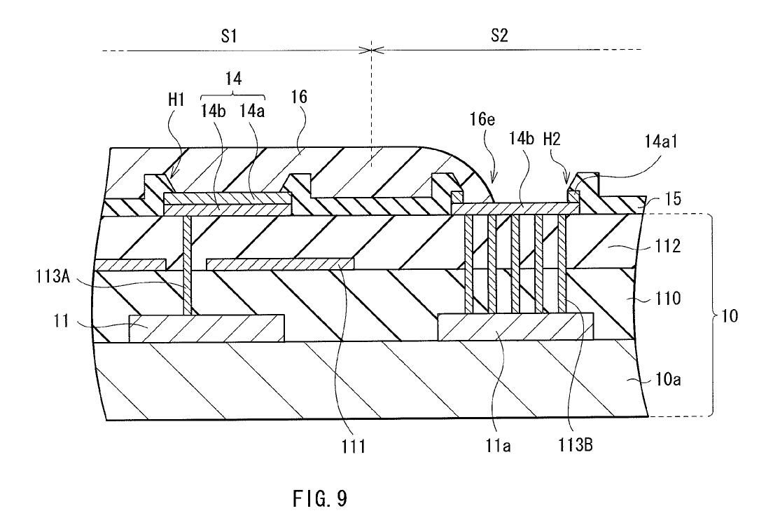

Next, as illustrated in FIG. 9, the organic layer 16 having the layered structure and made of the materials described above is formed at least over the entire display region. Here, the organic layer 16 is formed by, for example, vacuum deposition. For instance, when the light emitting layers of the respective colors of R, G, and B are laminated as the white light emitting layer, the luminescent materials of the respective colors are sequentially deposited by vacuum deposition, for example, over the entire substrate surface. In the peripheral region S2, the organic layer 16 is formed to extend so that the end section 16e of the organic layer 16 covers a part of the low-reflection conductive film 14b of the electrode pad 14P. A part of a surface of the low-reflection conductive film 14b in the electrode pad 14P is left exposed.

### (Process of Forming Second Electrode)

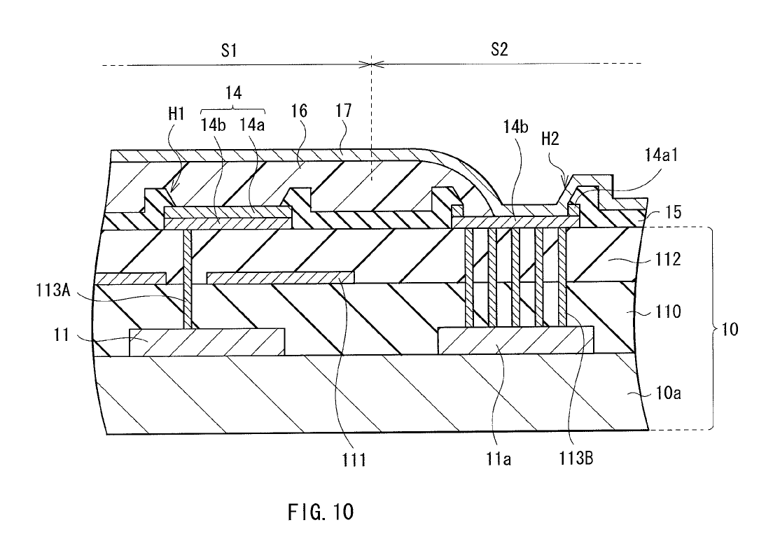

Subsequently, as illustrated in FIG. 10, the second electrode 17 made of the material described above is formed by, for example, sputtering, over the entire surface of the drive substrate 10. As a result, of the low-reflection conductive film 14b in the electrode pad 14P, the part exposed from the organic layer 16 is brought into contact with and thereby electrically connected to the second electrode 17.

Next, although not illustrated, the protective layer 18 made of the material described above is formed to cover the entire surface of the second electrode 17. Subsequently, the drive substrate 10 and the sealing substrate 20 are adhered to each other by using an adhesive layer. This completes the organic EL display 1 illustrated in FIG. 1.

### [Operation and Effects]

In the organic EL display 1, when a driving current based on an image signal is supplied to each subpixel (the EL device section 13A) through the first electrode 14 and the second electrode 17, the light emission is caused by the electron-hole recombination in the organic layer 16 (the white light emitting layer) at each of the EL device sections 13A. Of the white light of the light emission thus caused, light emitted towards the first electrode 14 side (downward) is reflected by the first electrode 14 and the like, and then outputted from an upper part of the sealing substrate 20. On the other hand, light emitted towards the second electrode 17 side (upward) is directly outputted from the upper part of the sealing substrate 20 after passing through the second electrode 17. In leaving the sealing substrate 20, color light of R, G, and B is taken out as display light, by passing through the color filter not illustrated. In this way, full-color image display based on the top emission method is performed.

In the present embodiment, as described above, the first electrode 14 serving as the reflecting electrode is provided in the display region 51, and the electrode pad 14P used to take out the second electrode 17 is provided in the peripheral region S2, on the drive substrate 10. The first electrode 14 is configured using the laminated film that has the low-reflection conductive film 14b provided below the high-reflection conductive film 14a and having the reflectance lower that that of the high-reflection conductive film 14a. Meanwhile, the electrode pad 14P has a film structure corresponding to a part of such a laminated film (i.e., includes the conductive film made of the same material as that of the low-reflection conductive film 14b). After the first electrode 14 and the electrode pad 14P are formed in the same process, a part of the laminated film is selectively removed in the electrode pad 14P.

### COMPARATIVE EXAMPLE

In a case where a first electrode and an electrode pad are formed in the same process in a manner similar to the one described above, the first electrode and the electrode pad are made of the same conductive-film material. In this case, the same high reflective material as that of the first electrode is used for a part corresponding to the electrode pad. Therefore, the electrode pad becomes highly reflective, allowing external light to be readily reflected. In the organic EL display 1 using a silicon substrate as the substrate 10a in particular, it is difficult to secure a large width of a frame (the peripheral region S2) for the purpose of realizing a size reduction as well as high definition and thus, shading performance in the peripheral region S2 is poor. In contrast, when a low reflective material is used as the conductive-film material of the first electrode and the electrode pad, external light reflection outside the peripheral region is possibly suppressed, but light extraction efficiency in the display region drops because of a reduction in the reflectance.

In the present embodiment, in contrast, the first electrode 14 and the electrode pad 14P each have the configuration as described above. Therefore, while these elements are formed in the same process, the first electrode 14 is allowed to exhibit the function of the high-reflection conductive film 14a, and the electrode pad 14P is allowed to exhibit the function of the low-reflection conductive film 14b. Hence, while high light extraction efficiency is ensured by the high-reflection conductive film 14a in the display region S1, external light reflection is suppressed by the low-reflection conductive film 14b in the peripheral region S2. It is to be noted that, in the electrode pad 14P, a part of the high-reflection conductive film 14a remains on an edge of the low-reflection conductive film 14b, but this has substantially no influence on the external light reflection.

In addition, the low-reflection conductive film 14b is configured using, for example, titanium, titanium nitride, or an alloy containing titanium. Therefore, when an indium-oxide-based material or a MgAg co-deposited film is used as the material of the second electrode 17, for example, satisfactory ohmic contact between the second electrode 17 and the electrode pad 14P is allowed to be ensured. Aluminum usually exhibits poor ohmic properties with respect to an indium-oxide-based material or a MgAg co-deposited film. Therefore, adoption of a layered structure like that in the present embodiment improves selectivity of materials of the second electrode 17, as compared with a case in which aluminum is used for an electrode pad.

Moreover, the organic layer 16 is formed to extend so as to cover the part of the electrode pad 14P. Thus, the second electrode 17 is formed to slope gently along a surface shape of the organic layer 16, and thereby the second electrode 17 is prevented from having breaks (gaps) or becoming locally thin, over a range covering a region on the electrode pad 14P. This improves production yield.

In the present embodiment, as described above, the first electrode 14 serving as the reflecting electrode is provided in the display region S1, and the electrode pad 14P is provided in the peripheral region S2, on the drive substrate 10. Further, the first electrode 14 includes the laminated film in which the high-reflection conductive film 14a is laminated on the low-reflection conductive film 14b, and the electrode pad 14P has the structure including the low-reflection conductive film 14b of the laminated film. This allows suppression of the external light reflection in the electrode pad 14P, while allowing a high reflection function to be exhibited in the first electrode 14. Therefore, a size reduction and high definition are achievable, without reducing visibility of a displayed image.

### Second Embodiment

### [Configuration]

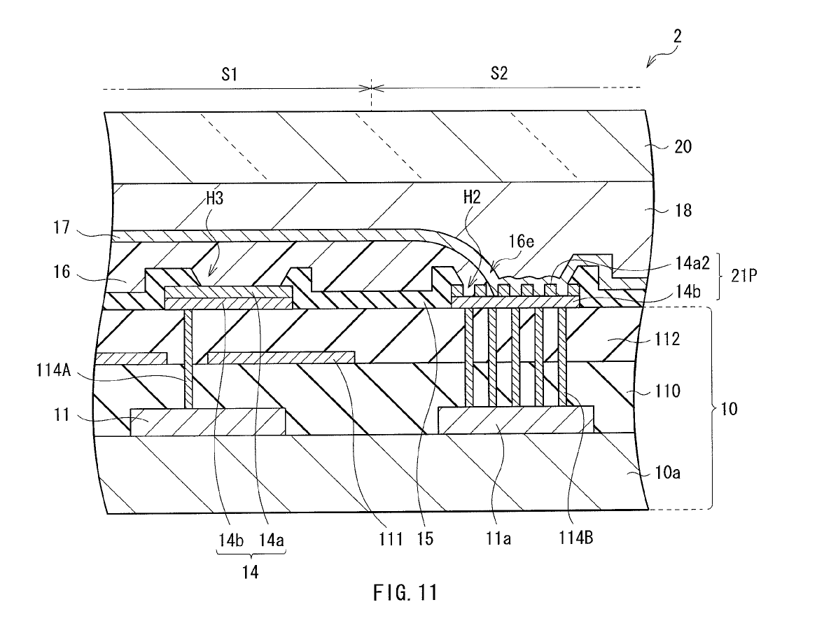

FIG. 11 illustrates a cross-sectional configuration of an organic EL display (an organic EL display 2) according to a second embodiment of the disclosure. Like the organic EL display 1 of the first embodiment, the organic EL display 2 causes light emission based on a top emission method, for example, and a plurality of EL device sections 13A are disposed in a matrix, for instance, on a drive substrate 10. It is to be noted that the same elements as those of the first embodiment will be provided with the same characters as those of the first embodiment, and the description thereof will be omitted as appropriate.

In the drive substrate 10, a drive circuit including a TFT 11 is disposed on a substrate 10a, as in the first embodiment. Further, a first insulating film 110, a wiring layer 111, and a second insulating film 112 are disposed on the substrate 10a to cover the TFT 11. In the first insulating film 110 and the second insulating film 112, a contact layer 114A is embedded in a region corresponding to the EL device section 13A, and a contact layer 114B is embedded in a region corresponding to an electrode pad 21P, respectively.

The contact layers 114A and 114B are each formed by filling a contact hole passing through the first insulating film 110 and the second insulating film 112, with a conductive material (e.g., tungsten), as in the first embodiment. The contact layer 114A electrically connects a first electrode 14 of the EL device section 13A to an electrode of the TFT 11. The contact layer 114B electrically connects a conductive film (a low-reflection conductive film 14b) of the electrode pad 21P to a wiring layer 11a. In the present embodiment however, as will be described later in detail, a surface shape of each of the contact layers 114A and 114B (namely, a surface facing the first electrode 14 and a surface facing the electrode pad 21P) has a protruding shape, unlike the contact layers 113A and 113B of the first embodiment.

Like the first embodiment described above, the EL device section 13A causes light emission based on, for example, the top emission method. For instance, the first electrode 14, an organic layer 16, and a second electrode 17 are provided on the second insulating film 112 of the drive substrate 10. Further, on the first electrode 14, an inter-pixel insulating film 15 is formed over an entire surface of the drive substrate 10. The inter-pixel insulating film 15 has an opening H3 facing the first electrode 14 and an opening H2 facing the electrode pad 21P.

In the present embodiment however, a region where the opening H3 is formed is different from a region where the opening H1 is formed in the first embodiment. Specifically, the opening H3 is formed in a region not facing the contact layer 114A. In other words, the inter-pixel insulating film 15 is formed to cover a region facing the contact layer 114A.

### (Electrode Pad 21P)

In the present embodiment, the electrode pad 21P corresponding to a part of a laminated film of the first electrode 14 is provided in a peripheral region S2 around a display region S1, as a wiring-connection pad of the second electrode 17, like the first embodiment. Specifically, the electrode pad 21P has at least the low-reflection conductive film 14b in the laminated film of the first electrode 14. In the electrode pad 21P, a high-reflection conductive film 14a is provided only in a selective part (a part not facing the contact layer 114B, namely, a high reflection section 14a2) on the low-reflection conductive film 14b. In other words, in the electrode pad 21P, the high-reflection conductive film 14a in a part facing the contact layer 114B on the low-reflection conductive film 14b is selectively removed. As will be described later in detail, after the laminated film including the high-reflection conductive film 14a and the low-reflection conductive film 14b is formed in the same process as that of the first electrode 14, the electrode pad 21P is formed by selectively removing a part of the high-reflection conductive film 14a through use of a technique different from that of the first embodiment.

The electrode pad 21P is in contact with the second electrode 17 in the opening H2 of the inter-pixel insulating film 15, and thereby electrical connection with the second electrode 17 is ensured. Here, the organic layer 16 is formed to extend from the display region S1 so as to cover a part of the electrode pad 21P in the peripheral region S2, and an end section 16e of the organic layer 16 gently slopes towards the electrode pad 21P, in the present embodiment as well. The second electrode 17 is formed over the entire surface of the drive substrate 10, along a slope of the organic layer 16. In a region exposed from the organic layer 16 on the electrode pad 21P, the second electrode 17 is formed to cover the high reflection section 14a2 and the low-reflection conductive film 14b. The electrical connection between the electrode pad 21P and the second electrode 17 is thereby ensured.

On the second electrode 17, a protective layer 18 is formed and a sealing substrate 20 is adhered, as in the first embodiment.

### [Production Method]

The organic EL display 2 as described above may be produced as follows, for example.

### (Process of Forming Drive Substrate)

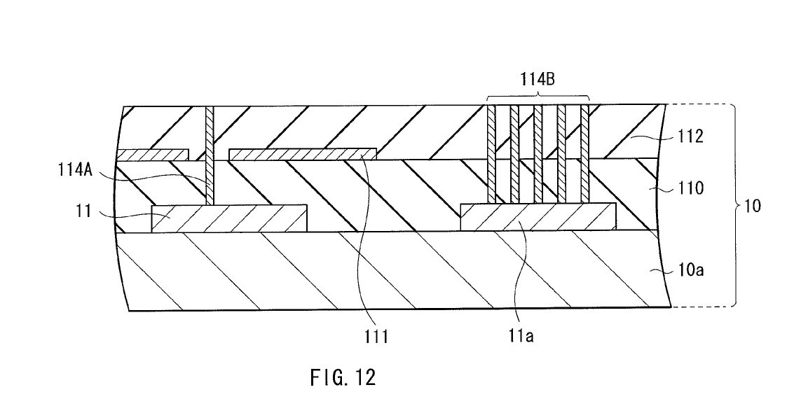

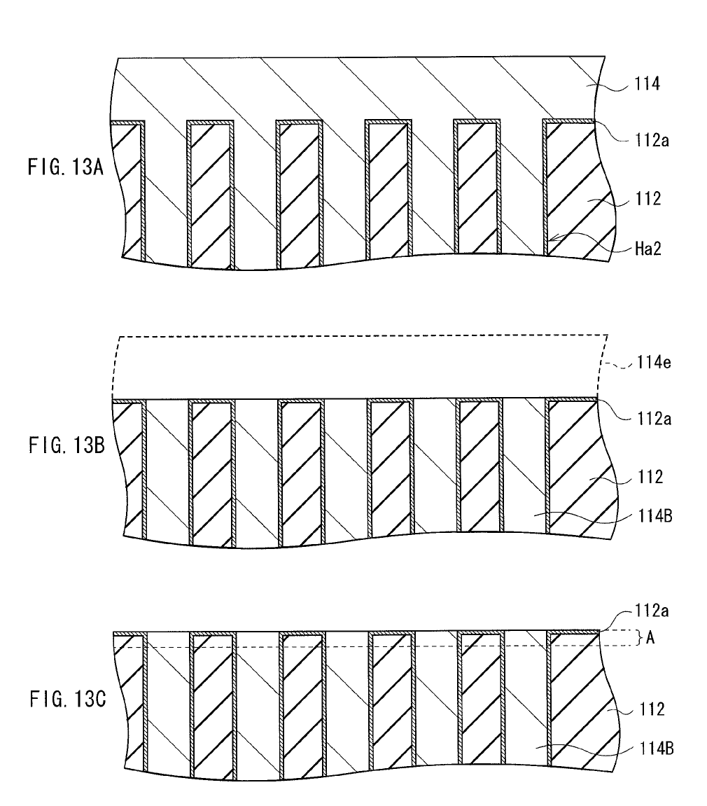

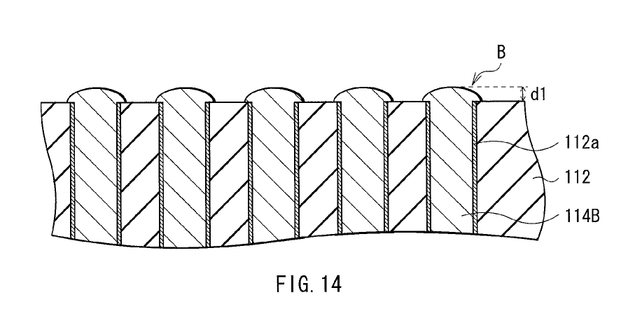

First, in a manner similar to the first embodiment, the drive circuit including the TFT 11 is formed on the substrate 10a made of the material described above (e.g., amorphous silicon) by undergoing a predetermined thin film process. Subsequently, the first insulating film 110, the wiring layer 111, and the second insulating film 112 are formed on the substrate 10a. The contact layers 114A and 114B are then formed, as illustrated in FIG. 12. With reference to FIGS. 13A to 13C and FIG. 14, a specific procedure of forming the contact layers 114A and 114B will be described below. It is to be noted that FIGS. 13A to 13C and FIG. 14 each illustrate only a part corresponding to the contact layer 114B.

Specifically, first, in a manner similar to the first embodiment, contact holes (Ha1 and Ha2) are formed in the first insulating film 110 and the second insulating film 112. These contact holes (Hal and Ha2) are then filled with, for example, a conductive film 114 made of a material such as tungsten, as illustrated in FIG. 13A. Specifically, a barrier metal 112a made of titanium or titanium nitride, for example, is formed on a surface of the second insulating film 112.

Next, of the conductive film 114, an unnecessary part (114e) formed as a layer on the second insulating film 112 is removed using, for example, CMP (Chemical Mechanical Polishing), as illustrated in FIG. 13B.

Subsequently, as illustrated in FIG. 13C, a region A on a surface side of each of the second insulating film 112 and the contact layer 114B is processed, and thereby a predetermined protruding shape B is formed on a surface of each of the contact layers 114B as illustrated in FIG. 14. Specifically, only selective parts of the region A are etched by, for instance, CMP using two kinds of slurry; slurry C1 and slurry C2. It is desirable that in the protruding shape B, a thickness d1 of a part protruding from the second insulating film 112 be, for example, about 10 nm to about 50 nm.

As the slurry C1, ordinary slurry used to polish a tungsten film (a solution which contains silica abrasive particles and to which iron nitrate or malonic acid is added) is employed. The slurry is used after the slurry is diluted with pure water as necessary (a mixing ratio of slurry to pure water is, for example, about 1:1), and about 1-3 (vol %) of a hydrogen peroxide solution is added to the slurry. As the slurry C2, there may be used a solution which contains about 4% to about 6% of colloidal silica in a major component (having a median abrasive-particle diameter of about 60 nm to about 90 nm) and has a pH of about 1-3. Mixing the slurry C1 and the slurry C2 at a ratio of about 1:3 to about 1:6 (or at a ratio in which the slurry C2 is further increased) allows the protruding shape B as described above to be formed on the surface of each of the contact layers 114B. It is to be noted that a form (the thickness d1) of the protruding shape B is allowed to be altered by adjusting the mixing ratio between the slurry C1 and the slurry C2.

In this way, at the drive substrate 10, the protruding shape B is formed on the surface of each of the contact layers 114A and 114B.

### (Process of Forming First Electrode and Electrode Pad)

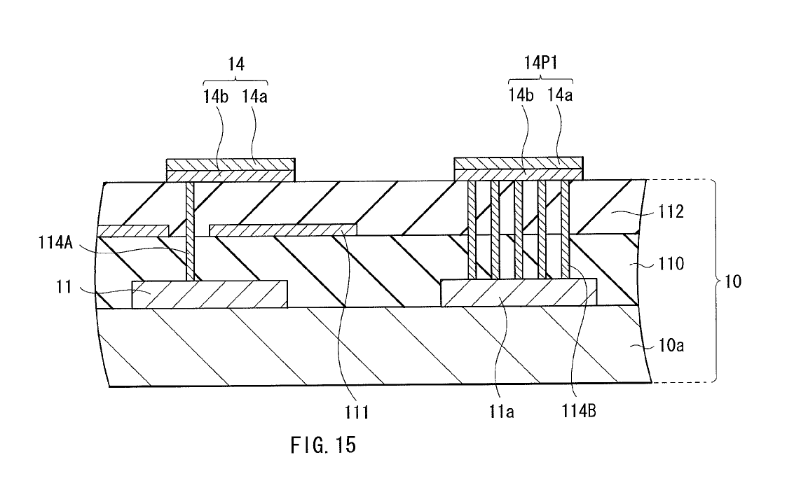

Next, as illustrated in FIG. 15, the first electrode 14 including the low-reflection conductive film 14b and the high-reflection conductive film 14a is formed on the drive substrate 10, in a manner similar to the first embodiment. At the same time, the laminated film 14P1 having a similar structure is also formed in the peripheral region S2.

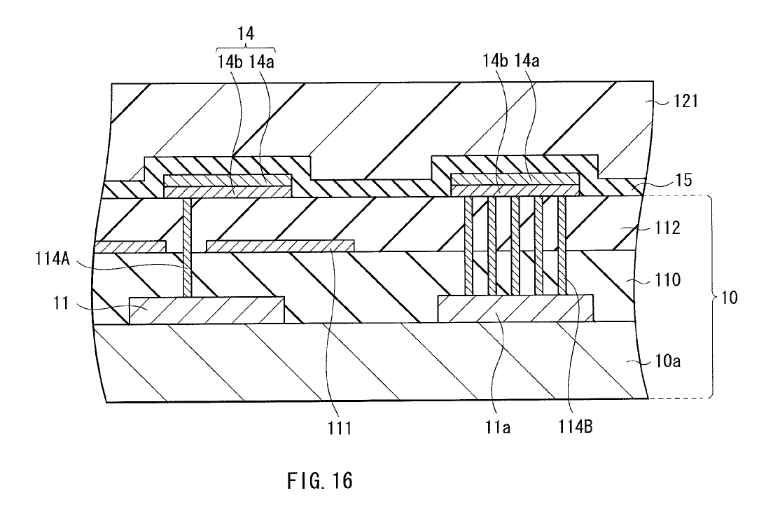

Subsequently, the inter-pixel insulating film 15 is formed over the entire surface of the drive substrate 10. Of the inter-pixel insulating film 15 thus formed, a region facing the first electrode 14 and a region facing the laminated film 14P1 are selectively removed by photolithography, and thereby the openings H3 and H2 are formed. Specifically, at first, the inter-pixel insulating film 15 and a photoresist film 121 are formed in this order, as illustrated in FIG. 16.

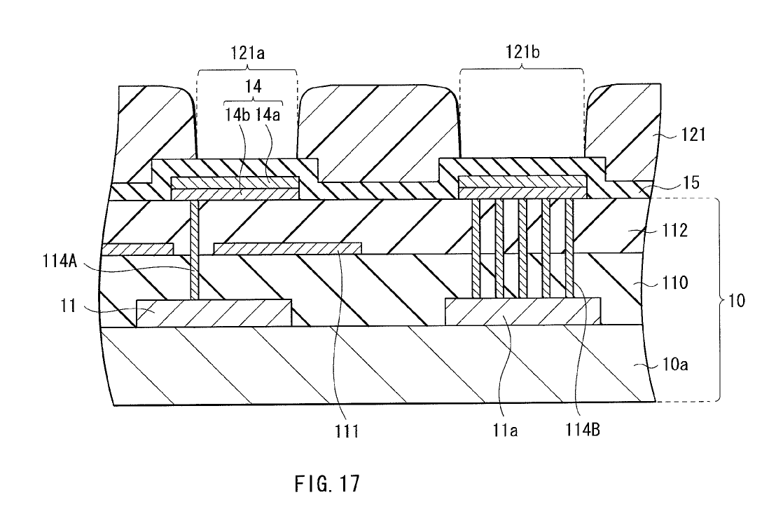

Afterwards, as illustrated in FIG. 17, selective regions of the photoresist film 121 are exposed. Thereby, openings 121a and 121b are formed in a region facing the first electrode 14 and a region facing the laminated film 14P1, respectively. At this moment, the opening 121a is formed in a region not facing the contact layer 114A, and the opening 121b is formed in a region facing the contact layer 114B.

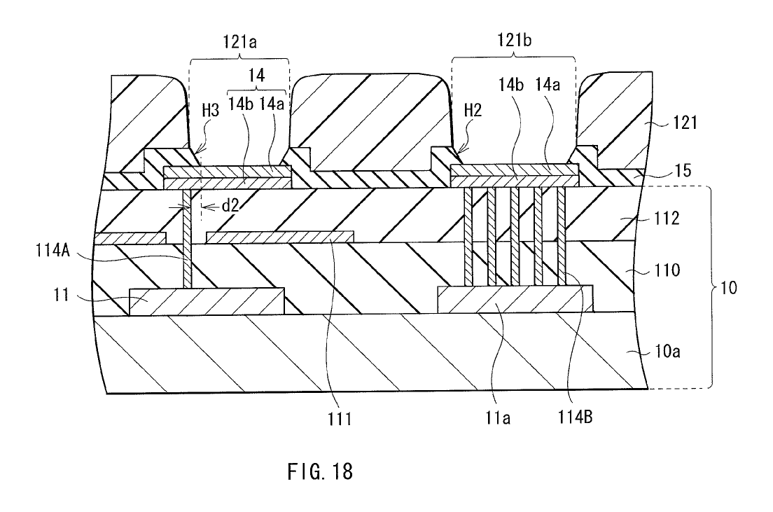

Next, as illustrated in FIG. 18, the openings H3 and H2 are formed in predetermined regions by performing dry etching using the photoresist film 121 as a mask. It is desirable that a distance d2 from an end of the opening H3 to the contact layer 114A be set in consideration of misalignment between a diameter of the contact layer 114A and the photoresist film 121 at the time of exposure. This allows the opening H3 to be provided so that a region on the contact layer 114A is covered by the inter-pixel insulating film 15.

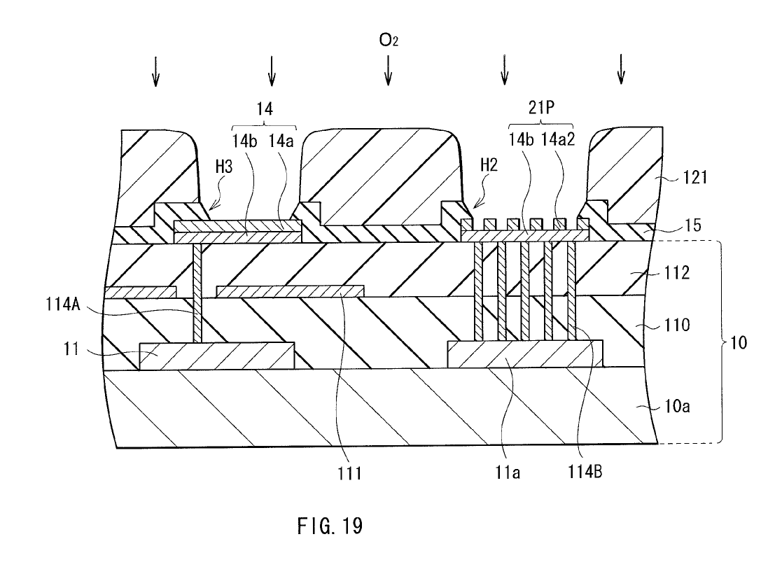

Subsequently, as illustrated in FIG. 19, plasma ashing using an oxygen gas, for example, is performed to remove the photoresist film 121. The plasma ashing is performed in a high-temperature atmosphere (at, for example, about 200° C. to about 400° C., and desirably, about 200° C. to about 300° C.). As a result, of the high-reflection conductive film 14a, only the region facing the contact layer 114B is selectively removed by effects of so-called thermal migration, and thereby, the electrode pad 21P including the low-reflection conductive film 14b and the high reflection section 14a2 remaining thereon is formed. It is to be noted that, in the first electrode 14, the contact layer 114A is covered by the inter-pixel insulating film 15 and the photoresist film 121 and therefore, the above-described event does not take place, and the high-reflection conductive film 14a is left unremoved.

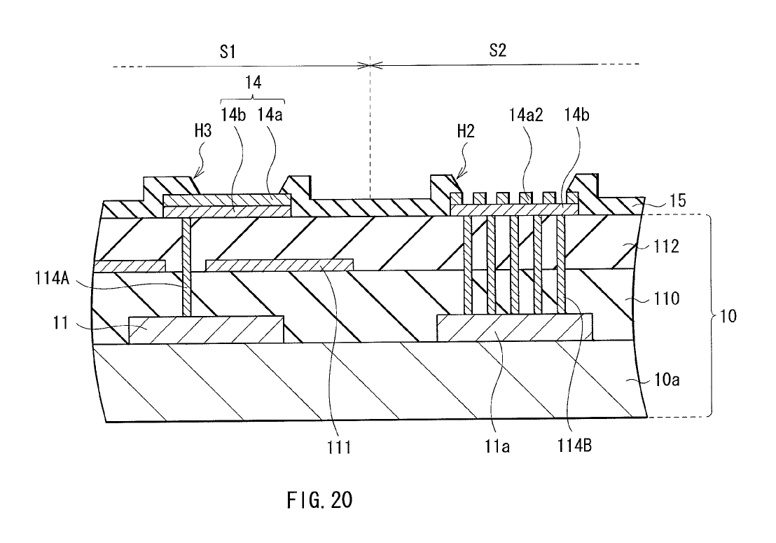

The photoresist film 121 is then removed as illustrated in FIG. 20. It is to be noted that in this removal process, immersion in a solution of electrolyte may be performed, which allows the high reflection section 14a2 (a residual part of the high-reflection conductive film 14a) to be reduced due to a battery effect.

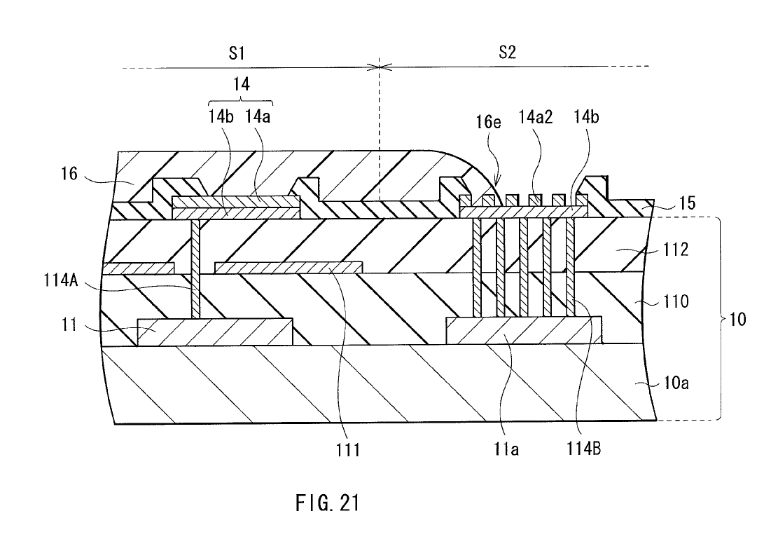

Next, as illustrated in FIG. 21, the organic layer 16 is formed in a manner similar to the first embodiment. The organic layer 16 is formed to extend so that the end section 16e of the organic layer 16 covers a part of the electrode pad 21P in the peripheral region S2 as in he first embodiment, and a part of a surface of the low-reflection conductive film 14b is left exposed.

Subsequently, as illustrated in FIG. 22, the second electrode 17 is formed in a manner similar to the first embodiment. As a result, of the low-reflection conductive film 14b in the electrode pad 21P, the part exposed from the organic layer 16 and the second electrode 17 are in contact with and thereby electrically connected to each other.

Next, although not illustrated, the protective layer 18 made of the material described above is formed to cover the entire surface of the second electrode 17 thus formed, and the drive substrate 10 and the sealing substrate 20 are then adhered to each other by using an adhesive layer. This completes the organic EL display 2 illustrated in FIG. 11.

### [Operation and Effects]

In the organic EL display 2 described above, when a driving current based on an image signal is supplied to each subpixel (the EL device section 13A), the light emission is caused in the organic layer 16 (a white light emitting layer), in a manner similar to the organic EL display 1 of the first embodiment. The white light of the light emission thus caused is reflected by the first electrode 14 and the like, or directly outputted from an upper part of the sealing substrate 20. Thereby, full-color image display in the top emission method is performed.

Further, on the drive substrate 10, the first electrode 14 serving as the reflecting electrode is provided in the display region S1, and the electrode pad 21P used to take out the second electrode 17 is provided in the peripheral region S2. The first electrode 14 includes the laminated film having the high-reflection conductive film 14a and the low-reflection conductive film 14b. The electrode pad 21P has a film structure corresponding to a part of such a laminated film (i.e., includes the conductive film made of the same material as that of the low-reflection conductive film 14b). After the first electrode 14 and the electrode pad 21P are formed in the same process, a part of the laminated film is selectively removed in the electrode pad 21P.

Therefore, in the present embodiment, while the first electrode 14 and the electrode pad 21P are formed in the same process, the first electrode 14 is allowed to exhibit the function of the high-reflection conductive film 14a, and the electrode pad 21P is allowed to exhibit the function of the low-reflection conductive film 14b. Therefore, substantially the same effects as those of the first embodiment are allowed to be obtained.

### [Overall Configuration of Organic EL Display and Pixel Circuit Configuration]

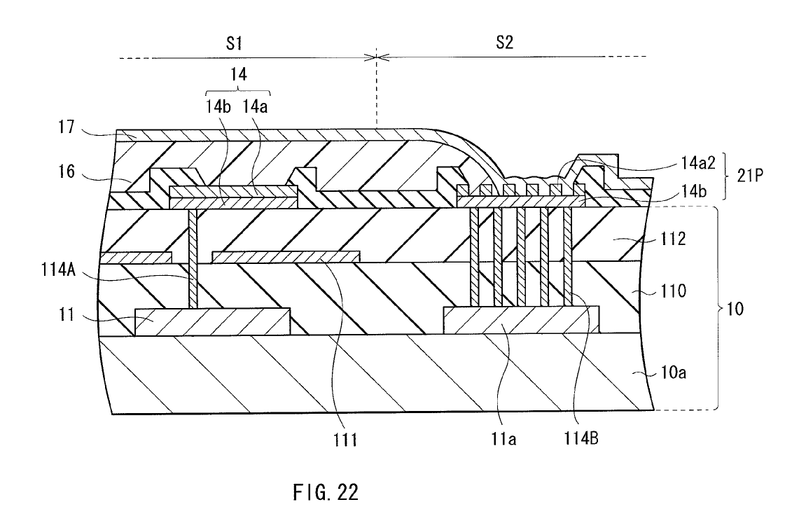

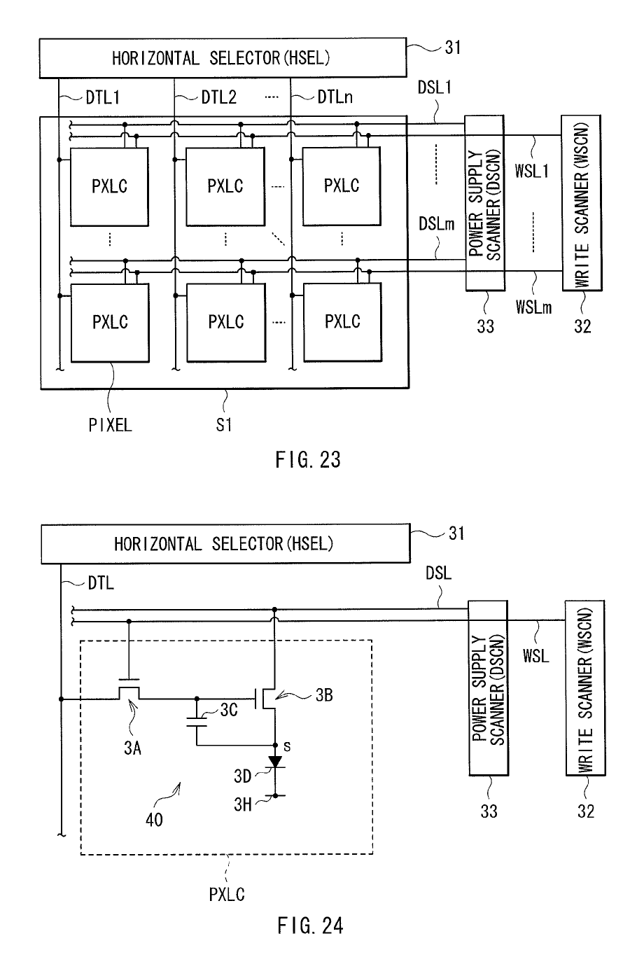

Now, there will be described an overall configuration of the organic EL display (each of the organic EL displays 1 and 2) and a pixel circuit configuration according to each of the embodiments. FIG. 23 illustrates an overall configuration including peripheral circuits of a display used as the organic EL display. As illustrated, on the drive substrate 10, for example, there is formed the display region S1 in which a plurality of pixels (subpixels) PXLC each including the organic EL device are arranged in a matrix. Provided around this display region S1 are a horizontal selector (HSEL) 31 serving as a signal-line driving circuit, a write scanner (WSCN) 32 serving as a scanning-line driving circuit, and a power supply scanner (DSCN) 33 serving as a power-line driving circuit.

In the display region S1, a plurality of (integer n) signal lines DTL1 to DTLn are arranged in a column direction, and a plurality of (integer m) scanning lines WSL1 to WSLm as well as power lines DSL1 to DSLm are arranged in a row direction. In addition, each of the pixels PXLC (any one of pixels corresponding to R, G, or B) is provided at an intersection of each of the signal lines DTL and each of the scanning lines WSL. Each of the signal lines DTL is connected to the horizontal selector 31, and an image signal is supplied from this horizontal selector 31 to each of the signal lines DTL. Each of the scanning lines WSL is connected to the write scanner 32, and a scanning signal (a selection pulse) is supplied from this write scanner 32 to each of the scanning lines WSL. Each of the power lines DSL is connected to the power supply scanner 33, and a power supply signal (a control pulse) is supplied from this power supply scanner 33 to each of the power lines DSL.

FIG. 24 illustrates a specific circuit-configuration example in the pixel PXLC. Each of the pixels PXLC has the pixel circuit 40 including an organic EL device 3D (equivalent to the EL device section 13A). The pixel circuit 40 is an active drive circuit having the sampling transistor 3A as well as the write transistor 3B, a retention capacitive device 3C, and the organic EL device 3D.

The sampling transistor 3A is connected to the scanning line WSL to which a gate thereof corresponds. Further, one of a source and a drain of the sampling transistor 3A is connected to the corresponding signal line DTL, and the other is connected to a gate of the write transistor 3B. The write transistor 3B is connected to the power line DSL to which a drain thereof corresponds, and a source thereof is connected to an anode of the organic EL device 3D. A cathode of the organic EL device 3D is connected to a ground wiring 3H. This ground wiring 3H is provided to be common to all the pixels PXLC. The retention capacitive device 3C is disposed between the source and the gate of the write transistor 3B.

The sampling transistor 3A samples a signal potential of an image signal supplied from the signal line DTL, by conducting in response to the scanning signal (the selection pulse) supplied from the scanning line WSL. The sampling transistor 3A then retains the signal potential at the retention capacitive device 3C. Upon being supplied with a current from the power line DSL set at a predetermined first potential (not illustrated), the write transistor 3B supplies a driving current to the organic EL device 3D, according to the signal potential retained at the retention capacitive device 3C. By the driving current supplied from the write transistor 3B, the organic EL device 3D is caused to emit light at intensity corresponding to the signal potential of the image signal.

In the circuit configuration described above, the sampling transistor 3A conducts in response to the scanning signal (the selection pulse) supplied from the scanning line WSL, and thereby the signal potential of the image signal supplied from the signal line DTL is sampled. This signal potential is then retained at the retention capacitive device 3C. Further, the current is supplied to the write transistor 3B from the power line DSL set at the first potential, and the driving current is supplied to the organic EL device 3D according to the signal potential retained at the retention capacitive device 3C. By the supplied driving current, each of the organic EL devices 3D is then caused to emit the light at the intensity according to the signal potential of the image signal. As a result, image display based on the image signal is performed in the organic EL display.

### APPLICATION EXAMPLES

Now, there will be described application examples to which the organic EL display 1 or the like described above is applicable. The organic EL display 1 or the like may be applied to electronic units in all fields, which display externally-input image signals or internally-generated image signals as still or moving images. The electronic units include television receivers, digital cameras, laptop computers, portable terminals such as portable telephones, video cameras, and the like.

### (Module)

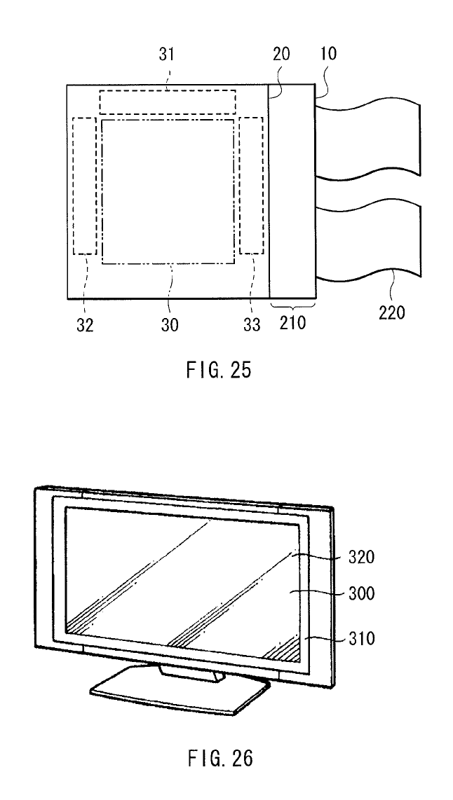

For instance, the organic EL display 1 or the like is incorporated, as a module illustrated in FIG. 25, into any of various kinds of electronic unit such as application examples 1 to 5 which will be described later. This module is formed, for example, by providing a region 210 exposed at one side of the drive substrate 10 from the sealing substrate 20. In this exposed region 210, an external connection terminal (not illustrated) is formed by extending wirings of the horizontal selector 31, the write scanner 32, and the power supply scanner 33. This external connection terminal may be provided with a flexible printed circuit (FPC) 220 for input and output of signals.

### APPLICATION EXAMPLE 1

FIG. 26 is an external view of a television receiver. This television receiver has, for example, an image-display screen section 300 that includes a front panel 310 and a filter glass 320. The image-display screen section 300 is equivalent to the organic EL display 1 or the like.

### APPLICATION EXAMPLE 2

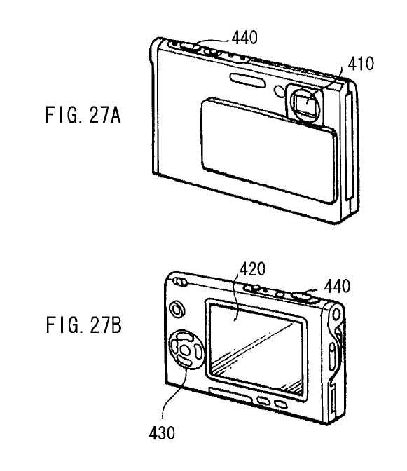

FIGS. 27A and 27B are external views of a digital camera. This digital camera includes, for example, a flash emitting section 410, a display section 420, a menu switch 430, and a shutter button 440. The display section 420 is equivalent to the organic EL display 1 or the like.

### APPLICATION EXAMPLE 3

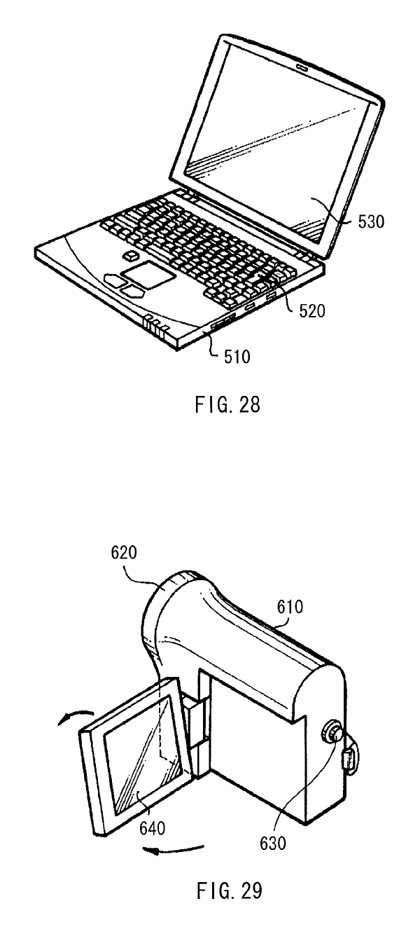

FIG. 28 is an external view of a laptop computer. This laptop computer includes, for example, a main section 510, a keyboard 520 provided to enter characters and the like, and a display section 530 displaying an image. The display section 530 is equivalent to the organic EL display 1 or the like.

### APPLICATION EXAMPLE 4

FIG. 29 is an external view of a video camera. This video camera includes, for example, a main section 610, a lens 620 disposed on a front face of this main section 610 to shoot an image of a subject, a start/stop switch 630 used in shooting, and a display section 640. The display section 640 is equivalent to the organic EL display 1 or the like.

### APPLICATION EXAMPLE 5

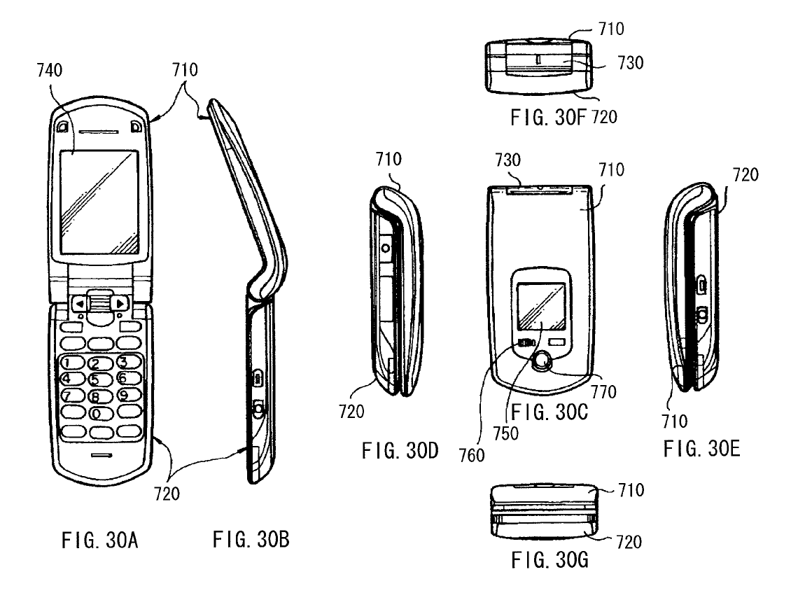

FIGS. 30A to 30G are external views of a portable telephone. This portable telephone is, for example, a unit in which an upper housing 710 and a lower housing 720 are connected by a coupling section (a hinge section) 730, and includes a display 740, a sub-display 750, a picture light 760, and a camera 770. The display 740 or the sub-display 750 is equivalent to the organic EL display 1 or the like.

The embodiments and the application examples have been described as examples, but the contents of the disclosure are not limited thereto and may be variously modified. For example, the material and thickness of each layer, or the film formation methods and conditions described in each of the embodiments and the like are not limited. Alternatively, other material and thickness, or other film formation methods and conditions may be employed.

Further, in each of the embodiments and the like, the case where the display is of an active matrix type organic EL display has been described. However, the disclosure is also applicable to an organic EL display of a passive matrix type. Furthermore, the configuration of the pixel driving circuit for active matrix driving is not limited to those described in the embodiments. Alternatively, a capacitive device and a transistor may be added as necessary.

It is possible to achieve at least the following configurations from the above-described exemplary embodiments of the disclosure.
(1) An organic EL display including:

a plurality of first electrodes provided in a display region on a drive substrate, the plurality of first electrodes each including a laminated film having two or more layers;

an organic layer provided on the plurality of first electrodes, the organic layer being provided over the entire display region and including a light emitting layer;

an electrode pad provided in a peripheral region around the display region on the drive substrate; and

a second electrode provided on the organic layer as well as the electrode pad,

wherein the laminated film includes
a first conductive film functioning as a reflective film, and
a second conductive film provided below the first conductive film, and having a reflectance lower than that of the first conductive film, and

the electrode pad corresponds to a part of the laminated film, and includes a conductive film made of a material same as that of the second conductive film.
(2) The organic EL display according to (1), wherein the organic layer is provided to extend from the display region to above the electrode pad in the peripheral region.
(3) The organic EL display according to (1) or (2), wherein the drive substrate includes:

a thin-film transistor;

an insulating film covering the thin-film transistor;

a first contact layer embedded in the insulating film, and electrically connecting the thin-film transistor to the first electrode; and

a second contact layer embedded in the insulating film, and electrically connecting a wiring layer to the electrode pad, the wiring layer being provided at a level same as the thin-film transistor.
(4) The organic EL display according to any one of (1) to (3), wherein the drive substrate includes a silicon substrate.
(5) The organic EL display according to any one of (1) to (4), wherein the electrode pad is formed by removing, from the laminated film, the first conductive film in a whole region or the whole region except an edge on the second conductive film.
(6) The organic EL display according to (3) or (4), wherein the electrode pad is formed by selectively removing, from the laminated film, the first conductive film in a region facing the second contact layer on the second conductive film.
(7) The organic EL display according to (6), further including:

an inter-pixel insulating film provided between the plurality of first electrodes and the organic layer, the inter-pixel insulating film being provided over an entire surface of the drive substrate and having a first opening and a second opening, the first opening facing each of the first electrodes, and the second opening facing the electrode pad,

wherein the first opening is formed in a region not facing the first contact layer, and

the second opening is formed in a region facing the second contact layer.
(8) The organic EL display according to any one of (1) to (7), wherein the first conductive film is made of aluminum (Al) or an alloy containing aluminum, and the second conductive film is made of titanium (Ti), titanium nitride (TiN), or an alloy containing titanium.
(9) The organic EL display according to any one of (1) to (8), wherein the second electrode is a transparent conductive film made of a compound of indium oxide, or a co-deposited film of magnesium and silver.
(10) The organic EL display according to any one of (1) to (9), wherein the organic layer includes a white light emitting layer.
(11) A method of producing an organic EL display, the method including:

forming a plurality of first electrodes in a display region on a drive substrate, the plurality of first electrodes each including a laminated film having two or more layers;

forming an organic layer provided on the plurality of first electrodes, the organic layer being provided over the entire display region and including a light emitting layer;

forming an electrode pad in a peripheral region around the display region on the drive substrate; and

forming a second electrode on the organic layer as well as the electrode pad,

wherein in forming the plurality of first electrodes,

a first conductive film and a second conductive film provided below the first conductive film are formed as the laminated film, the first conductive film functioning as a reflective film, and the second conductive film having a reflectance lower than that of the first conductive film, and

in forming the electrode pad,

a conductive film corresponding to a part of the laminated film is formed as the electrode pad, the conductive film being made of a material same as that of the second conductive film.
(12) The method of producing the organic EL display according to (11), wherein in forming the organic layer, the organic layer is formed to extend from the display region to above the electrode pad in the peripheral region.
(13) The method of producing the organic EL display according (11) or (12), wherein the drive substrate includes:

a thin-film transistor;

an insulating film covering the thin-film transistor;

a first contact layer embedded in the insulating film, and electrically connecting the thin-film transistor to the first electrode; and

a second contact layer embedded in the insulating film, and electrically connecting a wiring layer to the electrode pad, the wiring layer being provided at a level same as the thin-film transistor.
(14) The method of producing the organic EL display according to any one of (11) to (13), wherein the drive substrate includes a silicon substrate.
(15) The method of producing the organic EL display according to any one of (11) to (14), wherein in forming the first electrodes, the laminated film is formed in each of the display region and a part of the peripheral region, and

in forming the electrode pad, the electrode pad is formed by removing, from the laminated film formed in the peripheral region, the first conductive film in a whole region or the whole region except an edge on the second conductive film.
(16) The method of producing the organic EL display according to (13) or (14), wherein in forming the first electrodes, the laminated film is formed in each of the display region and a part of the peripheral region, and

in forming the electrode pad, the electrode pad is formed by selectively removing, from the laminated film formed in the peripheral region, the first conductive film in a region on the second conductive film, the region facing the second contact layer, the first conductive film being removed by a high-temperature treatment in plasma ashing using an oxygen gas.
(17) The method of producing the organic EL display according to (16), the method further including:

forming each of the first and second contact layers into a protruding shape that protrudes from an uppermost surface of the insulating film, in the drive substrate; and

forming an inter-pixel insulating film after forming the plurality of first electrodes and before forming the organic layer, the inter-pixel insulating film being formed over an entire surface of the drive substrate and having a first opening and a second opening, the first opening facing each of the first electrodes, and the second opening facing the electrode pad,

wherein in forming the inter-pixel insulating film, the first opening is formed in a region not facing the first contact layer, and

the second opening is formed in a region facing the second contact layer.
(18) An electronic unit including an organic EL display, the organic EL display including:

a plurality of first electrodes provided in a display region on a drive substrate, the plurality of first electrodes each including a laminated film having two or more layers;

an organic layer provided on the plurality of first electrodes, the organic layer being provided over the entire display region and including a light emitting layer;

an electrode pad provided in a peripheral region around the display region on the drive substrate; and

a second electrode provided on the organic layer as well as the electrode pad,

wherein the laminated film includes
a first conductive film functioning as a reflective film, and
a second conductive film provided below the first conductive film, and having a reflectance lower than that of the first conductive film, and

the electrode pad corresponds to a part of the laminated film, and includes a conductive film made of a material same as that of the second conductive film.

The disclosure contains subject matter related to that disclosed in Japanese Priority Patent Application JP 2011-191035 filed in the Japan Patent Office on Sep. 1, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An organic EL display comprising:
a plurality of first electrodes provided in a display region on a drive substrate, the plurality of first electrodes each including a laminated film having two or more layers;
an organic layer provided on the plurality of first electrodes, the organic layer being provided over the entire display region and including a light emitting layer;
an electrode pad provided in a peripheral region around the display region on the drive substrate; and
a second electrode provided on the organic layer as well as the electrode pad,
wherein the laminated film includes
a first conductive film functioning as a reflective film, and
a second conductive film provided below the first conductive film, and having a reflectance lower than that of the first conductive film, and
the electrode pad corresponds to a part of the laminated film, and includes a conductive film made of a material same as that of the second conductive film.

2. The organic EL display according to claim 1, wherein the organic layer is provided to extend from the display region to above the electrode pad in the peripheral region.

3. The organic EL display according to claim 1, wherein the drive substrate includes:
a thin-film transistor;
an insulating film covering the thin-film transistor;
a first contact layer embedded in the insulating film, and electrically connecting the thin-film transistor to the first electrode; and
a second contact layer embedded in the insulating film, and electrically connecting a wiring layer to the electrode pad, the wiring layer being provided at a level same as the thin-film transistor.

4. The organic EL display according to claim 1, wherein the drive substrate includes a silicon substrate.

5. The organic EL display according to claim 1, wherein the electrode pad is formed by removing, from the laminated film, the first conductive film in a whole region or the whole region except an edge on the second conductive film.

6. The organic EL display according to claim 3, wherein the electrode pad is formed by selectively removing, from the laminated film, the first conductive film in a region facing the second contact layer on the second conductive film.

7. The organic EL display according to claim 6, further comprising:
an inter-pixel insulating film provided between the plurality of first electrodes and the organic layer, the inter-pixel insulating film being provided over an entire surface of the drive substrate and having a first opening and a second opening, the first opening facing each of the first electrodes, and the second opening facing the electrode pad,
wherein the first opening is formed in a region not facing the first contact layer, and
the second opening is formed in a region facing the second contact layer.

8. The organic EL display according to claim 1, wherein the first conductive film is made of aluminum (Al) or an alloy containing aluminum, and the second conductive film is made of titanium (Ti), titanium nitride (TiN), or an alloy containing titanium.

9. The organic EL display according to claim 1, wherein the second electrode is a transparent conductive film made of a compound of indium oxide, or a co-deposited film of magnesium and silver.

10. The organic EL display according to claim 1, wherein the organic layer includes a white light emitting layer.

11. A method of producing an organic EL display, the method comprising:
forming a plurality of first electrodes in a display region on a drive substrate, the plurality of first electrodes each including a laminated film having two or more layers;
forming an organic layer provided on the plurality of first electrodes, the organic layer being provided over the entire display region and including a light emitting layer;
forming an electrode pad in a peripheral region around the display region on the drive substrate; and
forming a second electrode on the organic layer as well as the electrode pad,
wherein in forming the plurality of first electrodes,
a first conductive film and a second conductive film provided below the first conductive film are formed as the laminated film, the first conductive film functioning as a reflective film, and the second conductive film having a reflectance lower than that of the first conductive film, and
in forming the electrode pad,
a conductive film corresponding to a part of the laminated film is formed as the electrode pad, the conductive film being made of a material same as that of the second conductive film.

12. The method of producing the organic EL display according to claim 11, wherein in forming the organic layer, the organic layer is formed to extend from the display region to above the electrode pad in the peripheral region.

13. The method of producing the organic EL display according to claim 11, wherein the drive substrate includes:
a thin-film transistor;
an insulating film covering the thin-film transistor;
a first contact layer embedded in the insulating film, and electrically connecting the thin-film transistor to the first electrode; and
a second contact layer embedded in the insulating film, and electrically connecting a wiring layer to the electrode pad, the wiring layer being provided at a level same as the thin-film transistor.

14. The method of producing the organic EL display according to claim 11, wherein the drive substrate includes a silicon substrate.

15. The method of producing the organic EL display according to claim 11, wherein in forming the first electrodes, the laminated film is formed in each of the display region and a part of the peripheral region, and
in forming the electrode pad, the electrode pad is formed by removing, from the laminated film formed in the peripheral region, the first conductive film in a whole region or the whole region except an edge on the second conductive film.

16. The method of producing the organic EL display according to claim 13, wherein in forming the first electrodes, the laminated film is formed in each of the display region and a part of the peripheral region, and
in forming the electrode pad, the electrode pad is formed by selectively removing, from the laminated film formed in the peripheral region, the first conductive film in a region on the second conductive film, the region facing the second contact layer, the first conductive film being removed by a high-temperature treatment in plasma ashing using an oxygen gas.

17. The method of producing the organic EL display according to claim 16, the method further comprising:
forming each of the first and second contact layers into a protruding shape that protrudes from an uppermost surface of the insulating film, in the drive substrate; and
forming an inter-pixel insulating film after forming the plurality of first electrodes and before forming the organic layer, the inter-pixel insulating film being formed over an entire surface of the drive substrate and having a first opening and a second opening, the first opening facing each of the first electrodes, and the second opening facing the electrode pad,
wherein in forming the inter-pixel insulating film, the first opening is formed in a region not facing the first contact layer, and
the second opening is formed in a region facing the second contact layer.

18. An electronic unit including an organic EL display, the organic EL display comprising:
a plurality of first electrodes provided in a display region on a drive substrate, the plurality of first electrodes each including a laminated film having two or more layers;
an organic layer provided on the plurality of first electrodes, the organic layer being provided over the entire display region and including a light emitting layer;
an electrode pad provided in a peripheral region around the display region on the drive substrate; and
a second electrode provided on the organic layer as well as the electrode pad,
wherein the laminated film includes
a first conductive film functioning as a reflective film, and
a second conductive film provided below the first conductive film, and having a reflectance lower than that of the first conductive film, and
the electrode pad corresponds to a part of the laminated film, and includes a conductive film made of a material same as that of the second conductive film.
